(19) United States
(12) Patent Application Publication
(10) Pub. No.: US 2012/0190135 A1
(43) Pub. Date: Jul. 26, 2012

(54) MANUFACTURING METHOD AND MANUFACTURING APPARATUS FOR SEMICONDUCTOR DEVICE

(75) Inventors: Takayuki Ito, Oita (JP); Koji Kugino, Oita (JP)

(73) Assignee: KABUSHIKI KAISHA TOSHIBA, Tokyo (JP)

(21) Appl. No.: 13/231,055

(22) Filed: Sep. 13, 2011

(30) Foreign Application Priority Data
Jan. 25, 2011 (JP) 2011-013050

(51) Int. Cl. H01L 21/66; G21K 5/04

(52) U.S. Cl. 438/7; 250/397; 257/E21.527

(57) ABSTRACT

According to the embodiment, a manufacturing method for a semiconductor device includes detecting a sectional shape of an ion beam irradiated onto a semiconductor substrate and a beam current of the ion beam, calculating a beam current density which is the beam current per unit area based on the beam shape and the beam current detected in the detecting, and adjusting the ion beam based on the beam current density calculated in the calculating.

### CROSS-REFERENCE TO RELATED APPLICATIONS

This application is based upon and claims the benefit of priority from the prior Japanese Patent Application No. 2011-013050, filed on Jan. 25, 2011; the entire contents of which are incorporated herein by reference.

### FIELD

Embodiments described herein relate generally to a manufacturing method and a manufacturing apparatus for a semiconductor device.

### BACKGROUND

An ion injection apparatus has heretofore been known as one of manufacturing apparatus for a semiconductor device. The ion injection apparatus is configured to inject an ionized impurity atom (hereinafter described as “ion”) into a semiconductor substrate, in which various parameters for controlling an amount and a depth of ion injection can be changed.

Examples of the parameters include a beam current and an injection period, for example. In the ion injection apparatus, it is possible to adjust an ion injection state by preliminarily setting values of the parameters.

However, since a state of an ion source is subject to change, there is a problem that the state of injecting the ion into the semiconductor substrate is ultimately fluctuated even though the parameters are preliminarily set to appropriate values.

### BRIEF DESCRIPTION OF THE DRAWINGS

FIG. 1 is a diagram illustrating a manufacturing method according to one embodiment;

FIG. 2 is a diagram schematically illustrating a manufacturing apparatus according to another embodiment;

FIG. 3 is a block diagram illustrating a manufacturing apparatus according to the embodiment;

FIG. 4A is a diagram illustrating a relationship between a beam current and a reflection intensity difference, and FIG. 4B is a diagram illustrating a relationship between a beam current density and a reflection intensity difference;

FIG. 5A to FIG. 5C are diagrams illustrating a beam distribution obtained by the manufacturing apparatus according to the embodiment;

FIG. 6A to FIG. 6C are diagrams illustrating one example of beam adjustment performed by the manufacturing apparatus according to the embodiment; and

FIG. 7 is a flowchart illustrating process steps executed by the manufacturing apparatus according to the embodiment.

### DETAILED DESCRIPTION

According to the embodiment, a manufacturing method for a semiconductor device includes detecting a sectional shape of an ion beam irradiated onto a semiconductor substrate and a beam current of the ion beam, calculating a beam current density which is the beam current per unit area based on the beam shape and the beam current detected in the detecting, and adjusting the ion beam based on the beam current density calculated in the calculating.

Hereinafter, a method and an apparatus for manufacturing semiconductor device according to the embodiments will be described with reference to the accompanying drawings. The present invention is not limited to the embodiments described herein. In the following description, the manufacturing method for semiconductor device will be simply described as “manufacturing method”, and the manufacturing apparatus for semiconductor device will be simply described as “manufacturing apparatus”.

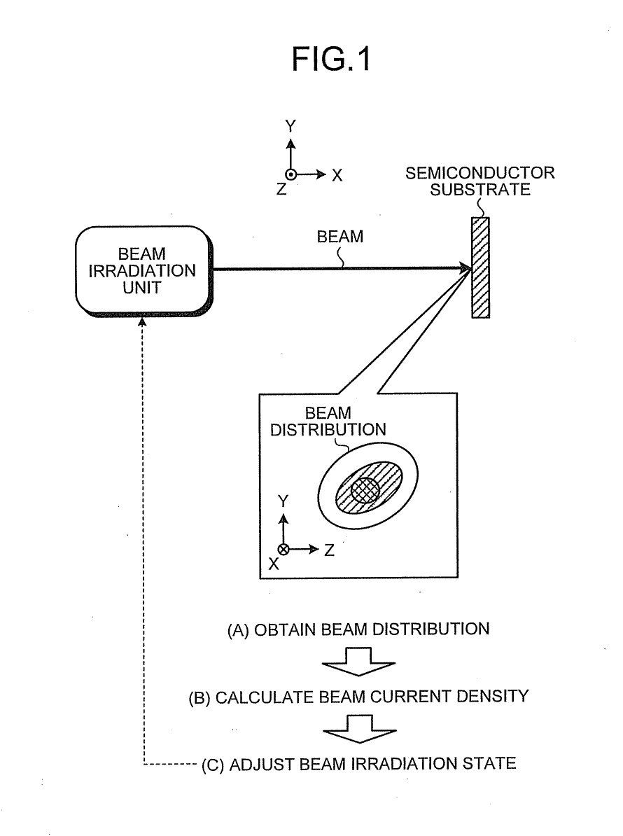

The manufacturing method according to the embodiment will be described by using FIG. 1. FIG. 1 is a diagram illustrating the manufacturing method according to the embodiment.

As illustrated in FIG. 1, the manufacturing method according to the embodiment includes a step of ionizing and injecting an impurity which decides device characteristics of a semiconductor device, i.e. a so-called ion injection step.

More specifically, in the manufacturing method according to the embodiment, an ion beam (hereinafter simply described as “beam”) generated by a beam irradiation unit is irradiated onto the semiconductor substrate (silicon wafer, for example). In the following description, a beam traveling direction is in a positive direction of an X axis in an XYZ coordinate system illustrated in FIG. 1.

Subsequently, the manufacturing method according to the embodiment obtains “beam distribution” of the beam irradiated onto the semiconductor substrate (see (A) of FIG. 1). “Beam distribution” is a distribution of beam currents on a YZ plane which is parallel to an irradiated surface of the semiconductor substrate, i.e. a distribution of beam intensities.

Here, the manufacturing method according to the embodiment calculates “beam current density” illustrating a beam current per unit area based on the obtained beam distribution (see (B) of FIG. 1). Subsequently, a beam irradiation state is adjusted based on the calculated beam current density (see (C) of FIG. 1). A dashed arrow in FIG. 1 indicates a feedback instruction to the beam irradiation unit.

As described above, the manufacturing method according to the embodiment monitors the beam current density of the beam irradiated onto the semiconductor substrate and performs the feedback control to the beam irradiation unit. The beam current density is kept within a predetermined numerical value range (hereinafter described as “predetermined range”) as a result of the feedback control which is performed as required.

Therefore, with the manufacturing method according to the embodiment, it is possible to appropriately adjust a state of injecting the ion into the substrate. In the case where an object of the ion injection is a MOSFET (Metal Oxide Semiconductor Field Effect Transistor), for example, it is possible to obtain stable MOSFET characteristics.

In the manufacturing method according to the embodiment, the beam current density is so controlled as to be adjusted to a largest possible value, and details of this feature will be described later in this specification. Hereinafter, a manufacturing apparatus to which the manufacturing method described by using FIG. 1 is adopted will be described.

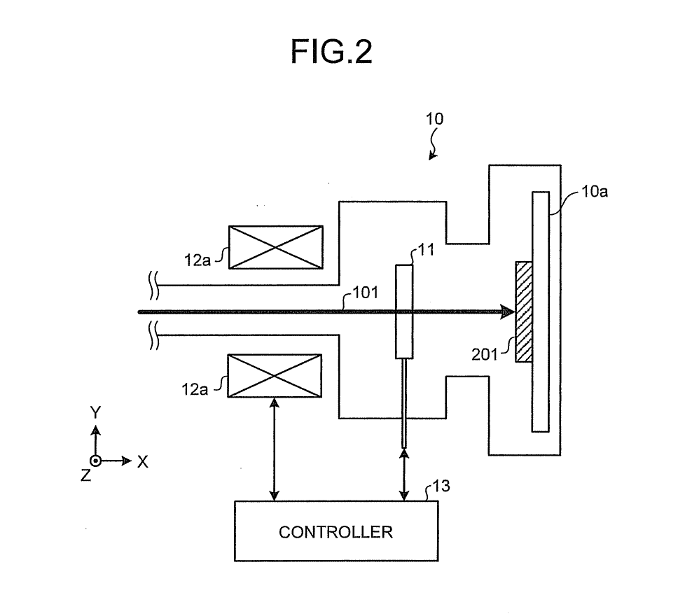

FIG. 2 is a diagram schematically illustrating a manufacturing apparatus 10 according to the embodiment. In FIG. 2, a part of constituent elements of the manufacturing apparatus 10 is illustrated from the viewpoint of simplification of illustration. As illustrated in FIG. 2, the manufacturing apparatus 10 supports a wafer 201 (corresponding to the semiconductor substrate illustrated in FIG. 1) by way of a holder 10a.

Also, the manufacturing apparatus 10 includes a beam detection probe 11 which measures a beam 101 irradiated onto the wafer 201. Also, the manufacturing apparatus 10 includes a quadrupole magnet 12a on the upper side (negative direction of X axis illustrated in FIG. 2) of the beam detection probe 11. The manufacturing apparatus 10 further includes a controller 13 which is connected to the beam detection probe 11 and the quadrupole magnet 12a.

The beam detection probe 11 is capable of moving to a predetermined position on a YZ plane illustrated in FIG. 2 by a not-illustrated driving unit (stepping motor, for example). The controller 13 gives the driving unit an instruction for moving the beam detection probe 11. Also, the controller 13 obtains various detection values from the beam detection probe 11 and adjust an irradiation state of the beam 101 by controlling the quadrupole magnet 12a based on the obtained detection values.

For example, the controller 13 adjusts a diameter and a shape of the beam 101 by giving instructions for changing a positive-negative combination of the four magnetic poles included in the quadrupole magnet 12a and for changing differences among voltages to be applied to the magnetic poles.

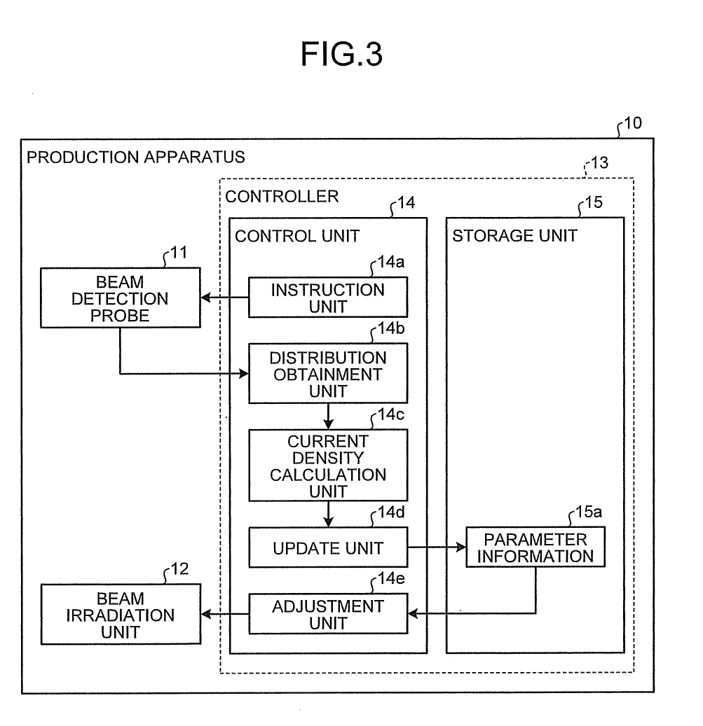

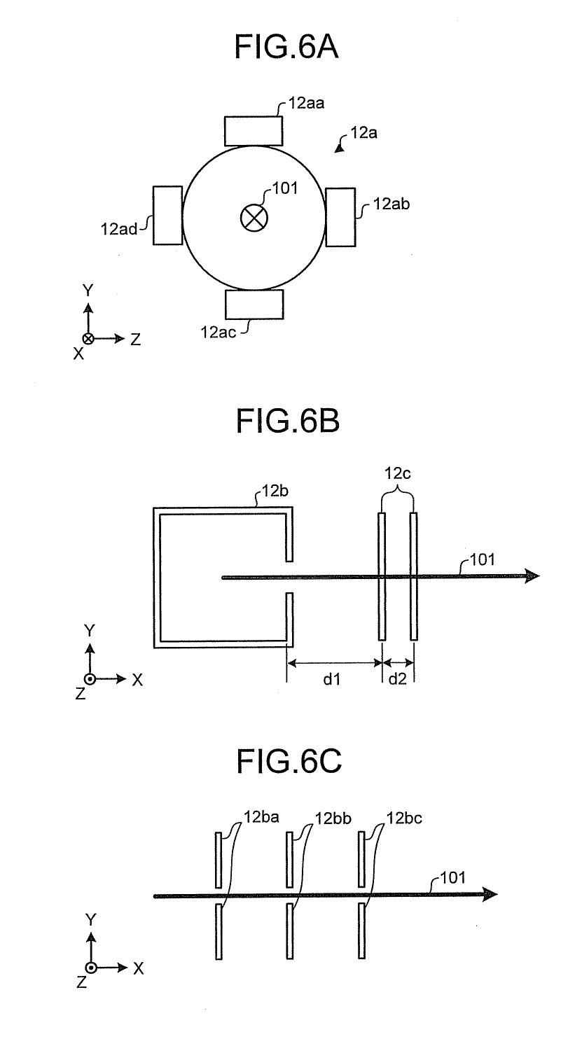

Details of the configuration of the controller 13 will be described later in this specification by using FIG. 3. Also, though the quadrupole magnet 12a is exemplified as the device for adjusting the irradiation state of the beam 101 in FIG. 2, another device may be used in combination. Therefore, details of the devices to be used for the beam adjustment will be described later in this specification by using FIG. 6A to FIG. 6C.

Hereinafter, the configuration of the manufacturing apparatus 10 illustrated in FIG. 2 will be described in more details by using FIG. 3. FIG. 3 is a block diagram illustrating the manufacturing apparatus 10 according to the embodiment. As illustrated in FIG. 3, the manufacturing apparatus 10 includes the beam detection probe 11, a beam irradiation unit 12, and the controller 13.

The controller 13 includes a control unit 14 and a storage unit 15. The control unit 14 includes an instruction unit 14a, a distribution obtainment unit 14b, a current density calculation unit 14c, an update unit 14d, and an adjustment unit 14e, and the storage unit 15 stores parameter information 15a.

As described above by using FIG. 2, the beam detection probe 11 is a measurement device for measuring the beam 101 (see FIG. 2). The beam detection probe 11 moves in the beam 101 in positive and negative directions of a Y axis (see FIG. 2) and positive and negative directions of a Z axis (see FIG. 2) according to instructions from the instruction unit 14a and sends the measured beam shape and beam current to the distribution obtainment unit 14b.

The beam irradiation unit 12 is a group of devices for irradiating the beam 101 (see FIG. 2) toward the wafer 201 and changing the irradiation state of the beam 101. Details of the group of devices will be described later in this specification by using FIG. 6A to FIG. 6C.

The controller 13 is connected to the beam detection probe 11 and the beam irradiation unit 12 and includes the control unit 14 and the storage unit 15. The control unit 14 performs an overall control of the manufacturing apparatus 10. The storage unit 15 is a memory device such as a hard disk drive and a nonvolatile memory.

The instruction unit 14a gives an instruction for locating the beam detection probe 11 at an arbitrary position on the YZ plane (see FIG. 2). More specifically, the instruction unit 14a causes the beam detection probe 11 to move to every positions of the sectional shape of the beam 101.

The distribution obtainment unit 14b receives the beam shape and the beam current measured by the beam detection probe 11. A beam current of each of partial regions included in the beam shape corresponds to the beam distribution. Also, the distribution obtainment unit 14b sends the obtained beam distribution to the current density calculation unit 14c.

The current density calculation unit 14c calculates the beam current density based on the beam distribution received from the distribution obtainment unit 14b. The beam current density means a beam current per unit area.

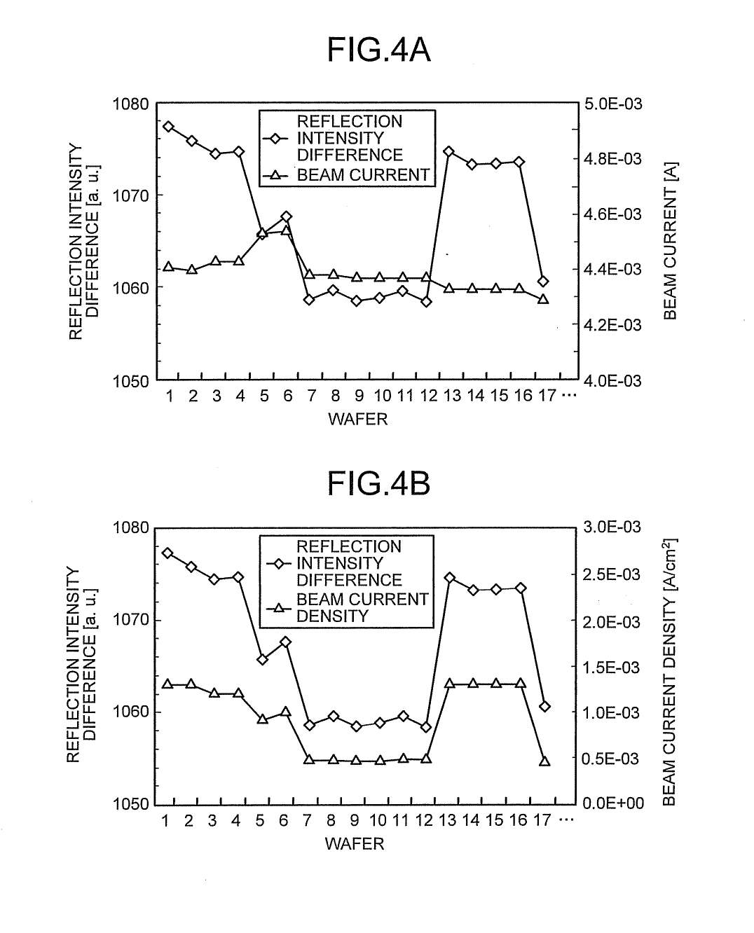

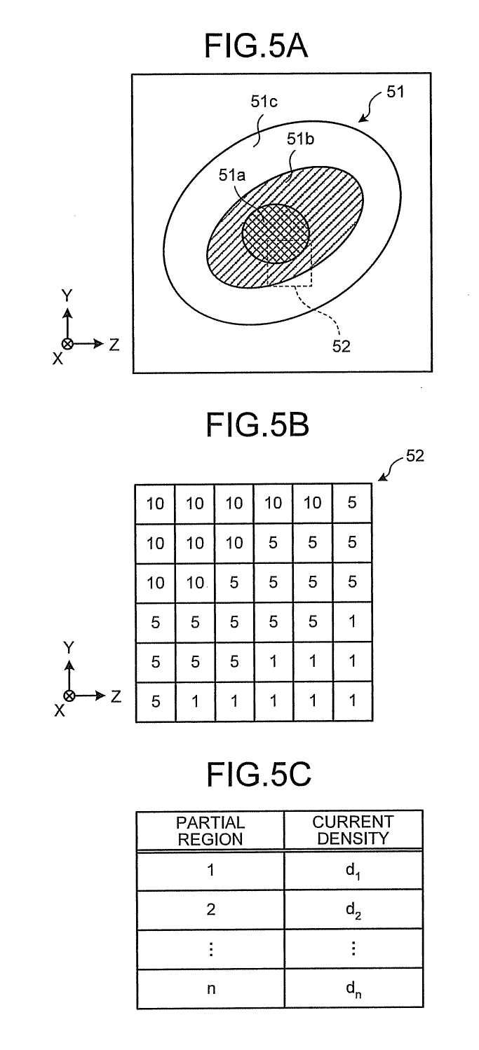

Hereinafter, the reason why the manufacturing apparatus 10 calculates the beam current density will be described by using FIG. 4A and FIG. 4B, and the beam distribution obtained by the distribution obtainment unit 14b will be described by using FIG. 5A to FIG. 5C. FIG. 4A and FIG. 4B are diagrams illustrating a relationship between the beam current and a reflection intensity difference and a relationship between the beam current density and the reflection intensity difference.

FIG. 4A illustrates the relationship between the beam current and the reflection intensity difference under an identical ion injection condition, and FIG. 4B illustrates the relationship between the beam current density and the reflection intensity difference under an identical ion injection condition. Also, since the minimum unit on the horizontal axis of FIG. 4A and FIG. 4B is one step of injection into the wafer 201, the horizontal axis may be considered as passage of time.

Further, on the vertical axis of FIG. 4A, the left scale is the reflection intensity difference (unit is a. u. (arbitrary unit)), and the right scale is the beam current (unit is A). Also, on the vertical axis of FIG. 4B, the right scale is the beam current density (unit is A/cm²), which is different from FIG. 4A.

The reflection intensity difference will hereinafter be described. In the case of injecting the ion into the wafer 201, a defect amount (primary defect amount) of the wafer 201 attributable to an ion injection is increased along with an increase in total amount (dose) of the injected ion. Therefore, it is possible to estimate the dose by measuring the primary defect amount.

As one of methods of measuring the primary defect amount, a method of using a difference between heat amplifications of a portion where a Si lattice linkage is cut and a portion where the Si silicon lattice linkage is not cut is known. More specifically, in the method, lattice vibration is caused by making a laser beam incident to the wafer 201, and the heat amplification difference is obtained as an intensity difference of reflected lights (reflection intensity difference).

It is possible to estimate the dose by obtaining the reflection intensity difference as described above. For example, it is possible to estimate that the dose is increased along with an increase in reflection intensity difference. Therefore, a fluctuation in dose in the wafer 201 is suppressed by maintaining the reflection intensity difference within a predetermined range.

As illustrated in FIG. 4A, any particular correlative relationship is not observed between the graph illustrating the passage of time of the reflection intensity difference and the graph illustrating the passage of time of the beam current. For example, it is difficult to find association between the reflection intensity difference change and the beam current change, such as a tendency that the beam current is increased when the reflection intensity difference decreases.

However, in the conventional example, only the attempt to adjust the dose by statically adjusting the beam current and the injection period in advance of the ion injection step is conducted. As apparent from FIG. 4A, however, a temporal fluctuation in a reflection intensity difference is observed under identical ion injection condition, and accordingly, it is difficult to suppress the fluctuation in dose.

In contrast, as illustrated in FIG. 4B, the correlative relationship is observed between the graph illustrating the passage of time of the reflection intensity difference and the beam current density. More specifically, the beam current density tends to be increased in the case where the reflection intensity difference increases, and the beam current density tends to be decreased in the case where the reflection intensity difference decreases.

Therefore, it is reasonable to infer that it is possible to maintain a constant reflection intensity difference, i.e. to maintain the dose to a constant value, by performing control for maintaining the beam current density to a constant value. Therefore, in the manufacturing apparatus 10 according to the embodiment, the current density calculation unit 14c calculates the beam current density, and the irradiation state of the beam 101 is so adjusted to keep the calculated beam current density within the predetermined range.

With such configuration, it is possible to suppress the fluctuation in reflection intensity difference, i.e. the fluctuation in dose. Therefore, it is possible to stabilize the characteristics of semiconductor devices to be produced.

Hereinafter, the beam distribution which is obtained by the distribution obtainment unit 14b will be described by using FIG. 5A to FIG. 5C. FIG. 5A to FIG. 5C are diagrams illustrating a beam distribution obtained by the manufacturing apparatus according to the embodiment. FIG. 5A illustrates one example of beam distribution; FIG. 5B illustrates an enlarged view of the beam distribution; and FIG. 5C illustrates one example of data of current density.

Also, the coordinate system illustrated in FIG. 5A and FIG. 5B are the same as that illustrated in FIG. 1 and FIG. 2.

Referring to FIG. 5A, a beam distribution 51 is expressed in the same manner as a so-called contour line. In the example illustrated in FIG. 5A, values of the beam currents are in a descending order of a region 51a, a region 51b, and a region 51c.

An outer periphery of the beam distribution 51, i.e. an outer periphery of the region 51c corresponds to an outer periphery of the beam 101 (see FIG. 2), and the shape of the outer periphery of the beam distribution 51 corresponds to the above-described beam shape. A distribution of the beam currents inside the beam shape is obtained by the above-described distribution obtainment unit 14b.

More specifically, the distribution obtainment unit 14b obtains the beam current of each of cells each having a predetermined area. The enlarged view illustrated in FIG. 5B corresponds to a region 52 illustrated in FIG. 5A. The values “1”, “5”, and “10” illustrated in FIG. 5B are examples used for indicating sizes of the beam currents.

The beam current obtained at one point inside the cell may be dealt as a beam current of the cell, or an average value of the beam currents obtained at a plurality of points of the cell may be dealt as a beam current of the cell.

Referring to FIG. 5C, the current density calculation unit 14c calculates a current density of each of partial areas (corresponding to the above-described cells) based on the beam distribution obtained by the distribution obtainment unit 14b. For example, when the area of the cell is “S” and the beam current is “I”, the current density is calculated as “I/S”.

When the serial number corresponding to each of the partial area is N (N is an integer of 1 to n) and the current density corresponding to each of the partial area is d_{N} (d₁ to dₙ), the current density calculation unit 14c selects a maximum value (peak current density) in a class of the current densities d_{N} as the beam current density.

The reason why the current density calculation unit 14c uses the maximum value of the current densities d_{N} as the beam current density is that the primary defect amount of the wafer 201 caused by the ion injection is considered to be increased along with an increase in current density d_{N}.

Referring back to FIG. 3, the description of the controller 14 will hereinafter be continued. The update unit 14d updates the parameter information 15a of the storage unit 15 based on the beam current density received from the current density calculation unit 14c. The parameter information 15a is a group of parameters which decide the irradiation state of the beam 101 emitted by the beam irradiation unit 12.

The update unit 14d updates the parameter information 15a in such a manner that the beam current density is changed to the one within a predetermined range. In the case where it is necessary to increase the beam current density, the update unit 14d updates the parameter information 15a in such a manner as to reduce the area of the beam shape, i.e. as to reduce the beam diameter, in place of increasing the beam current.

It is possible to set the above-described predetermined range by using a predetermined upper threshold value and a predetermined lower threshold value, for example. Also, the upper threshold value and the lower threshold value may be static values or may be dynamic values which are changed depending on a degree of a change of the beam current density.

The update unit 14d increases the beam current density by reducing the beam diameter in place of increasing the beam current for the purposes of attaining amorphization of the wafer 201 while avoiding a cost increase and an increase in apparatus load. More detailed description for this feature will be described below.

As a method for increasing an activation rate of an impurity diffusion layer in the wafer 201, a method of increasing the dose to be injected into the wafer 201 per unit period by increasing “beam current”, i.e. a method of increasing a dose rate, has been known.

The method aims to suppress restoration of a defect by self-annealing during the ion injection, to increase a primary defect amount per identical dose, and to attain amorphization of the wafer 201 by increasing the dose rate.

Since the amorphous wafer 201 has a high radiation factor, an effective annealing temperature is raised to reduce a secondary defect amount remaining after the annealing. Therefore, the method is known to activate a highly concentrated injection ion and, therefore, to be useful for formation of a good quality impurity diffusion layer in which a leak current is suppressed.

However, since it is necessary to increase a flow rate of an ion source gas in order to stably increase the beam current, a vicinity of a source member is easily worn and entails a cost increase and an increase in apparatus load. Also, since a maximum value of the beam current tends to decrease due to a temporal change of the apparatus, a failure in increasing the beam current can occur just when the increase is required.

Accordingly, when the beam current density is increased by reducing the beam diameter in place of increasing the beam current as described above, it is possible to increase the primary defect amount per identical dose and to attain the amorphization of the wafer 201 while avoiding the cost increase and an increase in apparatus load.

Hereinafter, the adjustment unit 14e will be described. The adjustment unit 14e adjusts the irradiation state of the beam 101 by the beam irradiation unit 12 based on the parameter information 15a updated by the update unit 14d. Though the update unit 14d and the adjustment unit 14e are separately illustrated in FIG. 3, the adjustment unit 14e may include the update unit 14d.

Hereinafter, one example of beam adjustment by the adjustment unit 14e will be described by using FIG. 6A to FIG. 6C. FIG. 6A to FIG. 6C are diagrams illustrating examples of beam adjustment performed by the manufacturing apparatus 10 according to the embodiment. FIG. 6A illustrates the quadrupole magnet 12a; FIG. 6B illustrates an ion source chamber 12b and extracting electrodes 12c; and FIG. 6C illustrates slits provided inside the ion source chamber 12b.

As illustrated in FIG. 6A, the quadrupole magnet 12a includes four magnetic poles of a magnetic pole 12aa, a magnetic pole 12ab, a magnetic pole 12ac, and a magnetic pole 12ad. Also, each of the magnetic poles is formed of an electromagnet, for example.

It is possible to change the shape and the diameter of the beam 101 by changing voltage differences among the magnetic poles or by changing a combination of polarities (positive or negative) of each of the magnetic poles.

Referring to FIG. 6B, it is also possible to change the shape and the diameter of the beam 101 by changing a distance d1 between the ion source chamber 12 and the pair of extracting electrodes 12c or by changing a distance d2 between the pair of extracting electrodes 12c. A relative position between the ion source chamber 12b and the pair of extracting electrodes 12c may be changed on a YZ plane illustrated in FIG. 6B. It is possible to perform the position adjustment by a not-illustrated driving unit (stepping motor, for example).

Referring to FIG. 6C, it is also possible to change the shape and the diameter of the beam 101 by changing slit widths (clearances for allowing the beam 101 to pass therethrough) of the slit 12ba, the slit 12bb, and the slit 12bc provided inside the ion source chamber 12b. Though the three slits are illustrated in FIG. 6C, the number of the slits is not limited.

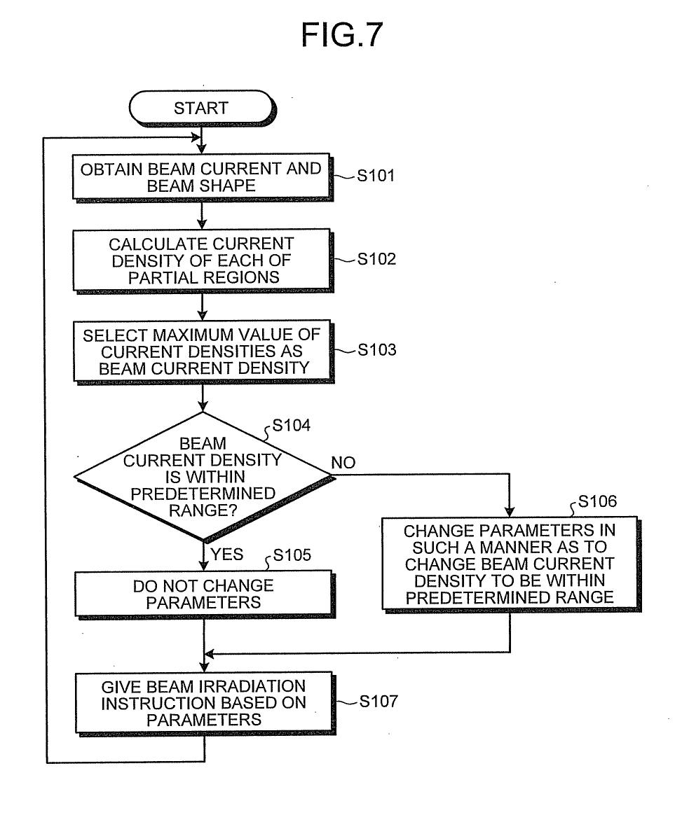

Hereinafter, process steps to be executed by the manufacturing apparatus 10 according to the embodiment will be described by using FIG. 7. FIG. 7 is a flowchart illustrating the process steps to be executed by the manufacturing apparatus 10 according to the embodiment.

As illustrated in FIG. 7, the distribution obtainment unit 14b obtains a beam current and a beam shape (Step S101), and then the current density calculation unit 14c calculates a current density of each of partial regions included in the beam shape (Step S102).

The current density calculation unit 14c selects a maximum value of the current densities as a beam current density (Step S103). Subsequently, the update unit 14d determines whether or not the beam current density is within the predetermined range (Step S104). In the case where the beam current density is within the predetermined range (Yes in Step S104), the update unit 14d does not change parameters included in the parameter information 15a (Step S105).

On the other hand, when determination conditions of Step S104 are not satisfied (No in Step S104), the update unit 14d changes the parameters included in the parameter information 15a in such a manner that the beam current density is changed to the one within the predetermined range (Step S106). The adjustment unit 14e gives a beam irradiation instruction based on the parameters included in the parameter information 15a to the beam irradiation unit 12 (Step S107), and then the steps in and after the S101 are repeated.

In the case of producing a semiconductor device as a semiconductor integrated circuit, a film formation step on the wafer 201, the above-described ion injection step to be executed by the manufacturing apparatus 10, an exposure step of transferring a mask pattern of a photomask to the water 201, an etching step of eliminating an unnecessary thin film or the like from the wafer 201, and the like are executed.

As described in the foregoing, in the manufacturing apparatus according to the embodiment, the beam detection probe detects the beam shape and the beam current of the ion beam irradiated onto the semiconductor substrate, and the current density calculation unit calculates the beam current density based on the detected value. After that, the adjustment unit adjusts the ion beam irradiation state based on the calculated beam current density. Therefore, according to the manufacturing apparatus according to the embodiment, it is possible to appropriately adjust the ion injection state for the semiconductor device.

In the foregoing embodiments, the case of calculating the current density of each of the partial regions included in the beam shape and dealing the maximum value of the calculated current densities as the beam current density is described. However, the case is not limitative, and an average value obtained by averaging the current densities corresponding to the partial regions over the entire partial regions may be used as the beam current density.

Also, though the case of adjusting the beam irradiation state in such a manner that the calculated beam current density is included within the predetermined range is described in the foregoing embodiments, the beam irradiation state may be adjusted in such a manner that the beam current density is converged to the predetermined threshold value.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a semiconductor device comprising:
detecting a sectional shape of an ion beam irradiated onto a semiconductor substrate and a beam current of the ion beam;.
calculating a beam current density which is the beam current per unit area based on the beam shape and the beam current detected in the detecting; and
adjusting the ion beam based on the beam current density calculated in the calculating.

2. The method according to claim 1, wherein
the adjusting comprises adjusting the ion beam in such a manner that the beam current density is included within a predetermined range.

3. The method according to claim 1, wherein
the adjusting comprises reducing an area of the beam shape in place of increasing the beam current in a case of increasing the beam current density in the ion beam.

4. The method according to claim 1, wherein
the calculating comprises calculating a current density of each of partial regions included in the beam shape and selecting a maximum value of the calculated current densities as the beam current density.

5. The method according to claim 1, wherein
the adjusting comprises adjusting the ion beam based on parameters updated in such a manner that the beam current density is included within the predetermined range in the case where the beam current density is not within the predetermined range.

6. The method according to claim 1, wherein
the calculating comprises calculating the current density of each of partial regions included in the beam shape and setting an average value of the calculated current densities as the beam current density.

7. The method according to claim 1, wherein
the adjusting comprises adjusting the ion beam in such a manner that the beam current density is converged to a predetermined threshold value.

8. The method according to claim 1, wherein
the adjusting comprises adjusting the ion beam by changing a voltage to be applied to a magnetic pole provided around a path of the ion beam or a polarity of the magnetic pole.

9. The method according to claim 1, wherein
the adjusting comprises adjusting the ion beam by changing a relative position between an ion source chamber and an extracting electrode to a direction which is parallel to the ion beam or a direction orthogonal to the ion beam.

10. The method according to claim 1, wherein
the adjusting comprises adjusting the ion beam by changing a slit width of a slit provided inside the ion source chamber.

11. A manufacturing apparatus for a semiconductor device comprising:
a detection unit configured to detect a beam shape of an ion beam irradiated onto a semiconductor substrate and a beam current of the ion beam;
a calculation unit configured to calculate a beam current density which is the beam current per unit area based on the beam shape and the beam current detected by the detection unit; and
an adjustment unit configured to adjust the ion beam based on the beam current density calculated by the calculation unit.

12. The apparatus according to claim 11, wherein
the adjustment unit configured to adjust the ion beam in such a manner that the beam current density is included within a predetermined range.

13. The apparatus according to claim 11, wherein
the adjustment unit configured to reduce an area of the beam shape in place of increasing the beam current in a case of increasing the beam current density in the ion beam.

14. The apparatus according to claim 11, wherein
the calculation unit configured to calculate a current density of each of partial regions included in the beam shape and selects a maximum value of the calculated current densities as the beam current density.

15. The apparatus according to claim 11, wherein
the adjustment unit configured to adjust the ion beam based on parameters updated in such a manner that the beam current density is included within the predetermined range in the case where the beam current density is not within the predetermined range.

16. The apparatus according to claim 11, wherein
the calculation unit configured to calculate the current density of each of partial regions included in the beam shape and sets an average value of the calculated current densities as the beam current density.

17. The apparatus according to claim 11, wherein
the adjustment unit configured to adjust the ion beam in such a manner that the beam current density is converged to a predetermined threshold value.

18. The apparatus according to claim 11, wherein
the adjustment unit configured to adjust the ion beam by changing a voltage to be applied to a magnetic pole provided around a path of the ion beam or a polarity of the magnetic pole.

19. The apparatus according to claim 11, wherein
the adjustment unit configured to adjust the ion beam by changing a relative position between an ion source chamber and an extracting electrode to a direction which is parallel to the ion beam or a direction orthogonal to the ion beam.

20. The apparatus according to claim 11, wherein
the adjustment unit configured to adjust the ion beam by changing a slit width of a slit provided inside the ion source chamber.
